(19) United States
(12) Patent Application Publication
(10) Pub. No.: US 2007/0069820 A1
(43) Pub. Date: Mar. 29, 2007

(54) Electronic parts for high frequency power amplifier

(76) Inventors: Kanji Hayata, Tokyo (JP); Hitoshi Akamine, Tokyo (JP); Hiroyuki Nagamori, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/527,518

(22) Filed: Sep. 27, 2006

(30) Foreign Application Priority Data
Sep. 28, 2005 (JP) 2005-281416

(51) Int. Cl. H03F 1/52

(52) U.S. Cl. 330/298

(57) ABSTRACT

An electronic part for a high frequency power amplifier is provided which is designed to constitute at least a part of a wireless communication system for performing feedback control by detecting an output power, and which can miniaturize a directional coupler. Also, the electronic part permits control of the output power with high accuracy without having any influence on a monitor voltage by a reflected wave propagating through a line of the directional coupler. The directional coupler includes a subline disposed in parallel to and in the vicinity of a part of a main line of an impedance matching circuit on the last output stage side of a power amplifier circuit, a capacitance element connected to between the main line and the subline, and a resistor element connected to between a constant potential point and a termination side of the subline. An output power detection circuit includes a first detection circuit for detecting an alternating current signal taken from a beginning side of the subline, a second detecting circuit for detecting an alternating current signal taken from a termination side of the subline, and a subtracting circuit for performing subtraction between an output of the first detection circuit and an output of the second detection circuit.

### CROSS-REFERENCE TO RELATED APPLICATION

The present application claims priority from Japanese patent application No. 2005-281416 filed on Sep. 28, 2005, the content of which is hereby incorporated by reference into this application.

### BACKGROUND OF THE INVENTION

The present invention relates to a technique useful for applications to electronic parts for a high frequency power amplifier which incorporates therein a high frequency power amplifier circuit to be used in a wireless communication system, such as a portable telephone or the like, for amplifying and outputting a transmission signal of high frequency, and a directional coupler to be used for detection of an output power required for feedback control of the output power.

In general, an output unit on a transmission side of a wireless communication device (mobile communication system), such as a portable telephone, is provided with a high frequency power amplifier circuit for amplifying a transmission signal modulated. Since in the conventional wireless communication device, an amplification factor of the high frequency power amplifier circuit is controlled according to the level of a transmission requirement from a control circuit, such as a baseband circuit or a microprocessor, the output power from the high frequency power amplifier circuit or an antenna is detected and subjected to feedback.

Detection of the output power in such a wireless communication device normally utilizes a directional coupler, which is simply called a coupler, a diode detection circuit, and the like. In most cases, the detection circuit is composed in the form of a semiconductor integrated circuit other than the high frequency power amplifier circuit. Furthermore, a semiconductor integrated circuit having the high frequency power amplification circuit formed therein, and discrete electronic parts, such as capacitance elements, for constituting the coupler and detection circuit are mounted on an insulating substrate, which constitutes a module. It is to be noted that the directional coupler is an element for taking out a traveling-wave component of the output via the capacitor formed between an output line (microstripline) formed on the discrete part or the insulating substrate, and a conductive layer disposed in parallel thereto. The directional coupler may generally be composed of the discrete part.

In the conventional output power detection circuit (detection circuit) of the high frequency power amplifier circuit using the directional coupler, the length of a transmission line included in the directional coupler is long, and thus the size of the coupler itself becomes large. This requires resistance elements on both ends of the coupler, or an external diode element for detecting an output from the coupler. Thus, the prior art module for amplification of high frequency power using the directional coupler also needs to use a number of semiconductor integrated circuits and/or electronic parts other than the high frequency power amplifier circuit, which makes it difficult to miniaturize the module.

The principle of the conventional directional coupler will be described below with reference to FIG. 2. In FIG. 2, reference character MML denotes a main line through which a transmission signal is transmitted, and reference character SML denotes a subline disposed in parallel to the main line MML. With this arrangement, since magnetic coupling and electric field coupling exist between the main line MML and the subline SML, when the transmission signal (electromagnetic wave) passes through the main line MML, a magnetic field occurs on the subline SML in a direction opposite to a traveling direction of the signal on the main line MML due to the magnetic coupling, thus causing a voltage Vm (H).

When impedance matching is not obtained between the main line MML and a transmission line or an antenna connected to the main line MML, apart or all of the transmission signal (a reflected wave) is returned in the direction opposite to the traveling or progressive direction of the transmission signal.

When the reflected wave passes through the main line MML, a current Ie (E) directed from the termination side to the beginning side of the subline SML, and a current Ie(E) directed towards the termination side thereof are caused due to the electric field coupling.

In the prior art directional coupler, the length of the line and the resistance of a resistor RL connected to the termination side of the subline SML are adjusted such that the voltage Vout_R=Ve (E)−Vm(H) at the termination side of the subline SML becomes zero so as to largely vary the strength of power taken according to the traveling direction of the electromagnetic wave. As a result, a large voltage (a traveling-wave component) represented by Vout_R=Ve (E)+Vm(H) is taken from the beginning side of the subline SML. In such a directional coupler, however, when the frequency for use in communications is in the 900 MHz band, for example, the line must have the length of about 3 mm, and have both ends thereof connected to resistors RLs, respectively, which makes it difficult to reduce the size of the module.

The present applicants have proposed and disclosed in a previous application for patent (see patent document 1) a module for a high frequency power amplifier in which a directional coupler includes a subline disposed in vicinity of and in parallel to a part of a main line of an impedance matching circuit disposed between an output terminal and an output node of a high frequency power amplifier circuit, a capacitance element connected to between the main line and the subline, and a resistor element connected to between the termination side of the subline and a constant potential point. In the module, an output power detection circuit is adapted to detect an alternating current signal taken via the capacitance element connected to the beginning side of the subline of the directional coupler, thereby permitting detection of the output power from the high frequency power amplifier circuit without using a conventional coupler, resulting in a reduction in size of the module.

Patent Document 1: Japanese Unexamined Patent Publication No. 2005-184631

Patent Document 2: Japanese Unexamined Patent Publication No. 2001-244899

### SUMMARY OF THE INVENTION

In the above-mentioned prior invention, the capacitance value of the capacitance element connected to between the main line and the subline, and the resistance value of the resistor element connected to between the termination side of the subline and the constant potential are adjusted appropriately to prevent a traveling wave propagating through the subline and a reflected wave propagating in a direction opposite to the direction of the traveling wave from having any influence on a monitor voltage taken from the coupler. The patent inventors, however, have found that when making the high frequency power amplifier module employing the directional coupler of the prior invention to measure the monitor voltage thereof, only the adjustment of the capacitance value between the main line and the subline, and of the resistance value of the termination side of the subline makes it difficult to completely eliminate the influence of the reflected wave propagating through the subline.

This is because there are influences of noise captured in the subline from the outside, and of the reflected wave from an antenna or a transmission line. At the time that this prior invention was developed, the use of the directional coupler proposed in the prior invention was able to satisfy a detection level required by a market even if the influence of the reflected wave on the monitor voltage was not eliminated completely. However, as the requirements by the market have become more stringent, it is necessary to reduce the influence of the reflected wave on the directional coupler, or to enhance the detection level of the traveling wave. Only the improvement of the coupler itself makes it relatively difficult to enhance a directional property thereof, that is, to reduce a reflected-wave component taken, while increasing a traveling-wave component.

Another prior invention similar to the present invention is disclosed in a patent document 2. In this prior invention, signal components of a traveling wave and a reflected wave are taken from both ends of a directional coupler via respective attenuators, and voltages of the respective signals are detected by voltage detection means including a logarithmic transformation circuit. Then, a comparator determines whether or not a difference between the voltage of the traveling wave and the voltage of the reflected wave exceeds a predetermined threshold value, thereby detecting the degree of the influence of the reflected wave.

An object of this prior invention is to determine the occurrence of an abnormal event in a load to give an alarm in a base station system when the difference between the voltages of the traveling wave and of the reflected wave exceeds a threshold value. Therefore, the prior invention of the patent document 2 does not have the same object as that of the present invention, an object of which is to control an output by amplifying a difference in voltage between traveling and reflected waves at a portable terminal, such as a portable phone, and by giving feedback to a bias circuit of a high frequency power amplifier circuit using the voltage difference as an output power detection signal.

Furthermore, the patent document 2 fails to disclose the length of the coupler. In such a case, it is normally supposed that the length of the coupler is one fourth of one wavelength of a transmission signal (for example, about 8.3 cm in the 900 MHz band). The prior invention as disclosed in the patent document 2 is directed to a transmission device positioned in the base station, while the present invention is directed to the portable terminal, such as the portable phone. For this reason, the prior invention does not need to pay so much attention to the miniaturization of a coupler and a device employing the coupler. It is understood that in the prior invention, the coupler having the length equal to one fourth of one wavelength of the transmission signal may be used without troubles.

It is therefore an object of the present invention to provide an electronic part for a high frequency power amplifier which can control an output power with high accuracy without having any influence of a reflected wave propagating through a line of a directional coupler on a detection voltage.

It is another object of the invention to provide a technique for detecting an output power which can miniaturize the directional coupler for taking an alternating current component of the output in the electronic part for the high frequency power amplifier, which constitutes a wireless communication system for detecting the output power, and controlling the feedback.

The above-mentioned and further objects and new features of the invention will become more apparent from the detailed description of the specification with reference to the accompanying drawings.

The brief description of typical aspects of the invention disclosed in the present application will be given below.

That is, an electronic part for a high frequency power amplifier according to one aspect of the invention includes an output power detection circuit for detecting an alternating current signal taken by a directional coupler, and for outputting a signal for performing feedback control of the power amplifier circuit. The directional coupler includes a pair of sublines respectively disposed in the vicinity of a part of a main line connected to the output of the power amplifier circuit, and in parallel to both sides of the part, a capacitance element connected to between the main line and each of the sublines, and a resistor element connected to an opposite end of each of the pair of sublines. The output power detection circuit includes a first detection circuit for detecting the alternating current signal taken from the beginning side of one of the sublines, a second detection circuit for detecting the alternating current signal taken from the termination side of the other subline, and a subtracting circuit for performing subtraction between an output of the first detection circuit and an output of the second detection circuit.

With the above-mentioned means, the alternating current signal taken from the beginning side of one subline mainly contains a traveling-wave component, while the alternating current signal taken from the termination side of the other subline mainly contains a reflected-wave component. Performing subtraction between the outputs of the signals detected by the respective detection circuits can provide a detection signal with little influence of the reflected wave.

In another aspect of the invention, the directional coupler is constructed such that one subline is provided on only one side of the main line, on both sides of which the sublines may be disposed in the previous aspect, with a capacitance element connected to between the beginning side of the one-side subline and the main line, and with a resistor element connected to between the termination side of the one-side subline and a constant potential, such as a ground level. The alternating current signal mainly containing the traveling-wave component is taken from the beginning side of the one-side subline, while the alternating current signal mainly containing the reflected-wave component is taken from the termination side of the one-side subline. Then, the difference between the voltages detected corresponds to an output detection signal. This can obtain the detection signal with little influence by the reflected wave, resulting in a decrease in the number of parts constituting the directional coupler, which enables miniaturization of the directional coupler, and further of the electronic part (module) for the high frequency power amplifier.

The effects provided by the typical aspects of the invention as disclosed in the present application will be briefly described below.

That is, according to the invention, in a wireless communication system for detecting the output power and for performing the feedback control, the electronic part for the high frequency power amplifier can be achieved which enables control of the output power with high accuracy without any influence on the monitor voltage by the reflected wave propagating through the line of the directional coupler. Also, this achieves a decrease in size of the directional coupler, and consequently, in size of the electronic part (module) for the high frequency power amplifier.

### BRIEF DESCRIPTION OF THE DRAWINGS

FIG. 1 is a circuit configuration diagram showing a configuration example of an output unit of a high frequency power amplifier (RF power module) to which a directional coupler of a first preferred embodiment of the invention is applied;

FIG. 2 is an explanatory diagram showing the principle of a conventional directional coupler;

FIGS. 3A and 3B are diagrams showing effects of the directional coupler of the first embodiment, in which FIG. 3A shows the effect of a traveling wave, and FIG. 3B shows the effect of a reflected wave;

FIG. 4 is an explanatory diagram showing a relationship between traveling-wave and reflected-wave components included in a first monitor voltage Vmon1 and taken from the directional coupler of the first embodiment to be input into an output detection circuit, and a reflected-wave component and a component having the same direction as that of the above-mentioned traveling-wave component, these components being included in a first monitor voltage Vmon2;

FIG. 5 is a graph showing a relationship between a load phase and an output power in an RF power module to which the directional coupler of the first embodiment is applied;

FIG. 6 is a circuit diagram showing a configuration of a test device for examining a relationship between the load phase and the output power in the RF power module to which the directional coupler of the first embodiment is applied;

FIG. 7 is a circuit configuration diagram showing a configuration example of an output unit of a high frequency power amplifier (RF power module) to which a directional coupler of a second preferred embodiment of the invention is applied;

FIG. 8 is an explanatory diagram for explaining a reason why an influence by the reflected wave is reduced in the second embodiment which is adapted to take a reflected-wave component from the termination side of a one-side subline;

FIG. 9 is a circuit configuration diagram showing the detailed configuration of the RF power module to which the directional coupler of the second embodiment is applied;

FIG. 10 is a circuit configuration diagram showing another embodiment of the output power detection circuit;

FIG. 11 is a circuit diagram schematically showing a configuration of gain adjuster included in the output power detection circuit of the second embodiment;

FIG. 12 is a perspective view showing an example of a device configuration of the power module of the embodiment;

FIG. 13 is a block diagram schematically showing an example of a configuration of a wireless communication system to which the invention is usefully applied; and

FIG. 14 is a block diagram schematically showing another example of the configuration of the wireless communication system to which the invention is usefully applied.

### DETAILED DESCRIPTION OF THE PREFERRED EMBODIMENTS

Reference will now be made to preferred embodiments of the invention based on the accompanying drawings.

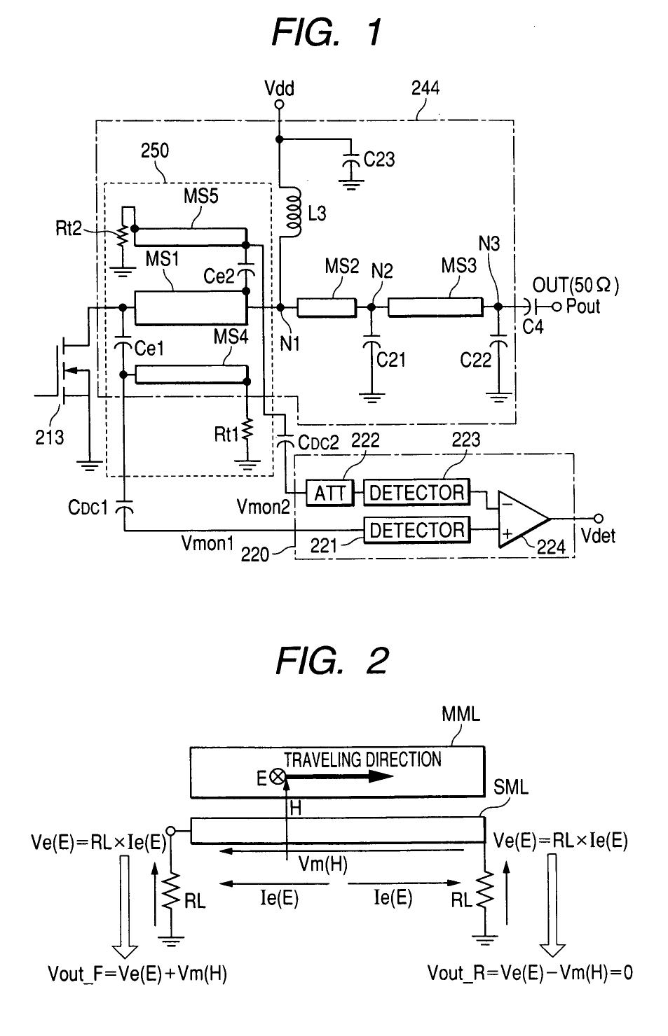

FIG. 1 shows an example of a configuration of an output unit of a high frequency power amplifier (hereinafter referred to as an RF power module) to which a directional coupler according to a first preferred embodiment of the invention is applied. Note that in the specification described herein, semiconductor chips and/or discrete parts are mounted on an insulating substrate, such as a ceramic substrate, on a surface of or inside which a printed wiring is formed. These parts are connected together through the above-mentioned printed wiring or a bonding wire so as to perform the respective predetermined functions, and the connected parts can be dealt with as one electronic part, which is hereinafter referred to as a module.

In FIG. 1, an element as denoted by reference numeral 213 is a FET for the power amplifier disposed at the last amplification stage for a high frequency power amplifier; a part as denoted by reference numeral 244 is an impedance matching circuit disposed between a drain terminal of the FET 213 for the power amplifier and an output terminal of the module; and a part as denoted by reference numeral 250 is a directional coupler. A part as denoted by reference numeral 220 is an output power detection circuit. As shown in FIG. 1, in the embodiment, a microstripline MS1 included in the impedance matching circuit 244 is shared as a main line between a directional coupler 250 and the matching circuit.

The impedance matching circuit 244 is constituted as the so-called π type matching circuit which includes micro strip lines MS1 to MS3 connected in series to a direct current cut capacitor between a drain terminal of the FET 213 for the power amplifier at the last stage and the output terminal of the module, a capacitor C21 connected to between a ground point and a connection node N2 between the microstriplines MS2 and MS3, and a capacitor C22 connected to between another ground point and a connection node N3 between the microstripline MS3 and a capacitor C4. To keep the impedance matching to the power source voltage terminal vdd, an inductor L3 is connected between the power source voltage terminal Vdd and a connection node N1 between the microstriplines MS1 and MS2, and a capacitor C23 is connected to between the power source voltage terminal Vdd and a ground point.

The directional coupler 250 includes the microstripline MS1 serving as a main line included in the impedance matching circuit 244, and the microstriplines MS4 and MS5 disposed as a subline in parallel to each other on both ends of the microstripline MS1. The directional coupler 250 includes a coupling capacitor Ce1 connected to between the beginning of the microstripline MS1 (an end of the drain terminal side of the FET 213) and the beginning of the microstripline MS4 for mainly taking the traveling-wave component, and a resistor Rt1 connected to between the termination of the microstripline MS4 and a ground point. Furthermore, the directional coupler 250 includes a coupling capacitor Ce2 connected to between the termination of the microstripline MS1 and the beginning of the microstripline MS5 for mainly taking the reflected-wave component, and a resistor Rt2 connected to between the termination of the microstripline MS5 and a ground point. Magnetic coupling is caused between the microstripline MS1, and the microstriplines MS4 and MS5, and electric field coupling is made by the capacitors Ce1 and Ce2.

The output power detection circuit 220 includes a first detection circuit 221 for detecting an alternating current component taken from the beginning of the subline MS4 of the directional coupler 250 via the direct current cut capacitor CDC1, an attenuator 222 for attenuating the alternating current component taken from the beginning of the subline MS5 via the direct current cut capacitor CDC2, and a second detection circuit 223 for detecting a signal attenuated. Also, the output power detection circuit 220 includes a subtracting circuit 224 for performing subtraction between an output of a first detection circuit 221 and an output of the second detection circuit 223 to ouput a detection output Vdet. The direct current cut capacitor CDC2 may be provided at the later stage of the attenuator 222, that is, between the attenuator 222 and the second detection circuit 223, or inside the attenuator 222.

The capacitors Ce1 and Ce2 for the electric field coupling of the directional coupler 250 may have a capacitance value of about 0.5 to 1 pF for use. The capacitors CDC1 and CDC2 are elements for blocking the direct current component, and may have a capacitance value of about 100 pF for use. The resistors Rt1 and Rt2 for use may have a resistance value of about 30 to 150 Ω. The direct current cut capacitors CDC1 and CDC2 have relatively large capacitance values so as to transmit the alternating current component sufficiently, and thus may be constituted of discrete parts (elements) for use. In contrast, the coupling capacitors Ce1 and Ce2 have small capacitance values, and thus may be inner capacitors for use, each consisting of a pair of patterns of conductive layers formed on the module substrate even in the form of a discrete part.

In this embodiment, the length of each of the microstriplines MS1 and MS4 is about 1 mm. The width of the MS4 is 0.1 mm, and the width of MS1 is set to be four to five times as long as that of MS4. The impedance of the microstripline MS1 is about 2 to 3 Ω. The distance between the microstriplines MS1 and MS4 is set to 0.1 mm. The same goes for the microstripline MS5.

The drain terminal of the FET 213 for the power amplifier connected to the beginning of the microstripline MS1 has an impedance of about 2 Ω, so that the impedance of the connection node N1 between the micro strip lines MS1 and MS2 is about 5 Ω. It should be noted that although in FIG. 1 the microstriplines MS1 to MS3 are separately formed, they may be sequentially formed, and the inductor L3 and the capacitors C21 and C22 may be connected to any points on the microstriplines. In this case, the length of the MS1 is about 1 mm or more (about 3 to 5 mm), and the length of the MS4 is about 1 mm.

In the embodiment, the main line included in the directional coupler may have only the length of about 1 mm, while the microstripline MS1 of the matching circuit may be used as a main line of the coupler, and the conductive layer formed on the module substrate may be used as the subline. This enables miniaturization of the module. One side coupler which consists of the microstriplines MS1 and MS4, the coupling capacitor Ce1, and the termination side resistor Rt1 is the same as that disclosed in the above-mentioned patent document 1.

As described in the patent document 1, the reason why the length of the microstripline MS1 is shorten is as follows. The directional coupler of the embodiment is connected to the drain terminal of the FET for the power amplifier 213, and the impedance of the drain terminal is about 2 Ω, which is very low. Thus, even if the microstripline is short, it can sufficiently transmit a change in magnetic field due to the strong magnetic coupling to the microstriplines MS4 and MS5 serving as the subline. Even if the impedance at the connection point is low, when the microstripline is short, its parasitic capacitance becomes small. Thus, only such a microstripline cannot transmit the change in electric field sufficiently due to its weak electric field coupling. Accordingly, in the directional coupler of the embodiment, the capacitor Ce1 is provided to compensate for the electric field coupling. This can obtain the miniature directional coupler which can monitor the output power sufficiently. Note that the thus-obtained directional coupler is hereinafter referred to as a power coupler.

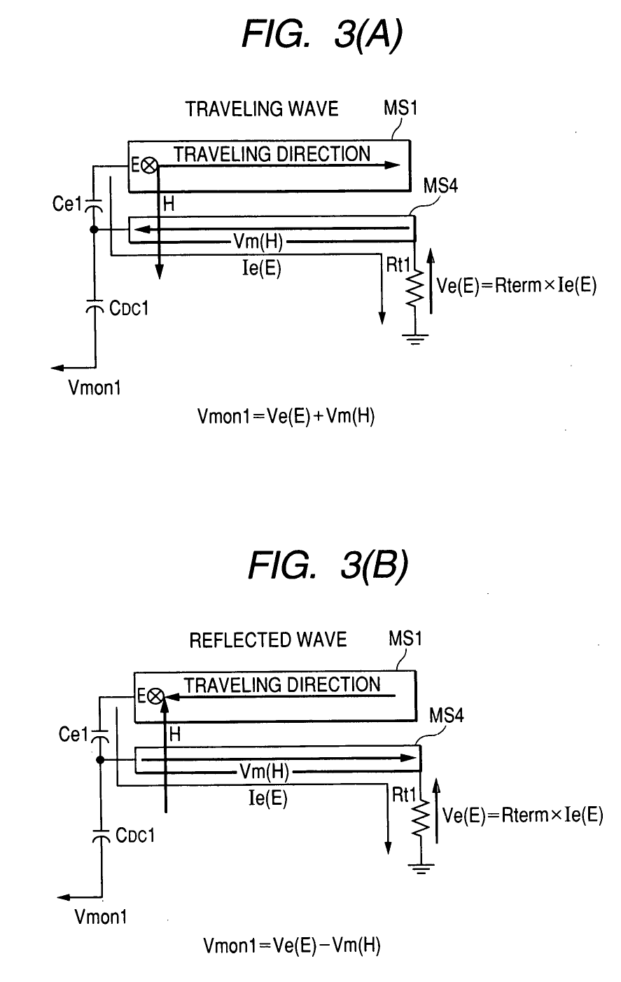

The power coupler of the embodiment is adapted to prevent the influence of the reflected wave on a coupling voltage (monitor voltage) by adjusting the capacitance value of the capacitor Ce1 and the resistance value of the resistor Rt1. More specifically, as shown in FIG. 3A, when a voltage caused by a traveling wave in the subline MS4 via the magnetic coupling is Vm(H), a current passing through the subline MS4 via the electric field coupling by the traveling wave is Ie(E), and a voltage caused by the current Ie (E) passing through the resistance Rt1 (resistance value Rterm) is Ve (E) , the monitor voltage Vmon1 is represented by the following equation: Vmon1=Ve(E)+Vm(H)=Rterm×Ie(E)+Vm(H)

In contrast, as shown in FIG. 3B, when a voltage caused by a reflected wave in the subline MS4 via the magnetic coupling is −Vm(H), a current passing through the subline MS4 via the electric field coupling by the reflected wave is Ie(E), and a voltage caused by the current Ie(E) passing through the resistance Rt (resistance value Rterm) is Ve(E), the monitor voltage Vmon1 is represented by the following equation: Vmon1=Ve(E)−−Vm(H)=Rterm×Ie (E)−Vm (H). In the power coupler of the embodiment, by adjusting the capacitance value of the capacitor Ce1 and the resistance value Rterm of the resistor Rt1, the monitor voltage Vmon1=Ve(E)−Vm (H), which is caused at the beginning of the subline by the reflected wave passing through the main line, is set to “zero(0)”.

Thus, the power coupler of the embodiment has the directional property, and can prevent the influence on the monitor voltage even when the load is varied. The capacitance value of the capacitor Ce2 and the resistance value of the resistor Rt2 on the subline MS5 side are selected to be equal to the capacitance value of the capacitor Ce1 and the resistance value of the resistor Rt1 thus determined, so that the voltage taken from the subline MS5 side can be prevented from being influenced readily by the traveling wave propagating through the main line.

Now, an attenuation factor N of the attenuator 222 will be described below. Even if the influence on the monitor voltage by the reflected and traveling waves propagating through the main line is reduced as mentioned above, any influence on the monitor voltage by a reflected wave of the traveling wave propagating through the sublines MS4 and MS5, by a reflected wave of the reflected wave (in the same direction as that of the traveling wave), or by noise captured in the sublines MS4 and MS5, cannot be eliminated completely. FIG. 4 shows a relationship between directions and sizes of a traveling-wave component FoutFw included in the monitor voltage Vmon1 on the traveling-wave side, a reflected-wave component FoutRw included in the monitor voltage Vmon1 on the traveling-wave side, a reflected-wave component RoutFw included in the monitor voltage Vmon2 on the reflected-wave side, and a traveling-wave component RoutRw included in the monitor voltage Vmon2 on the reflected-wave side.

Thus, according to the embodiment of the invention, the attenuation factor N of the attenuator 222 is set such that a voltage at which the reflected-wave component RoutFw of the alternating current signal taken from the subline MS5 side is detected is at the same level as that of a voltage at which the reflected-wave component FoutRw of the alternating current signal taken from the subline MS5 side is detected. That is, the N is set in order to satisfy the equation of FoutRw=RoutFw/N. Thus, the FoutRw and the RoutFw are offset to each other, and the output voltage Vdet of the subtracting circuit 224 is a voltage (FoutFw−RoutRw/N) . This voltage is proportional to a voltage obtained by subtracting a voltage at which a signal provided by attenuating the traveling-wave component RoutRw of the monitor voltage Vmon2 on the reflected-wave side by a factor of 1/N is detected, from a voltage at which the traveling-wave component FoutFw included in the monitor voltage Vmon1 is detected. The traveling-wave component RoutRw included in the monitor voltage Vmon2 on the reflected-wave side is a reflected wave of the reflected wave propagating the subline MS5, and is so small that the signal RoutRwN obtained by attenuating the component by a factor of 1/N is regarded as “zero(0)”. As a result, the output voltage Vdet of the subtracting circuit 224 can be regarded as a voltage proportional to the voltage at which the traveling-wave component FoutFw included in the monitor voltage Vmon1 is detected.

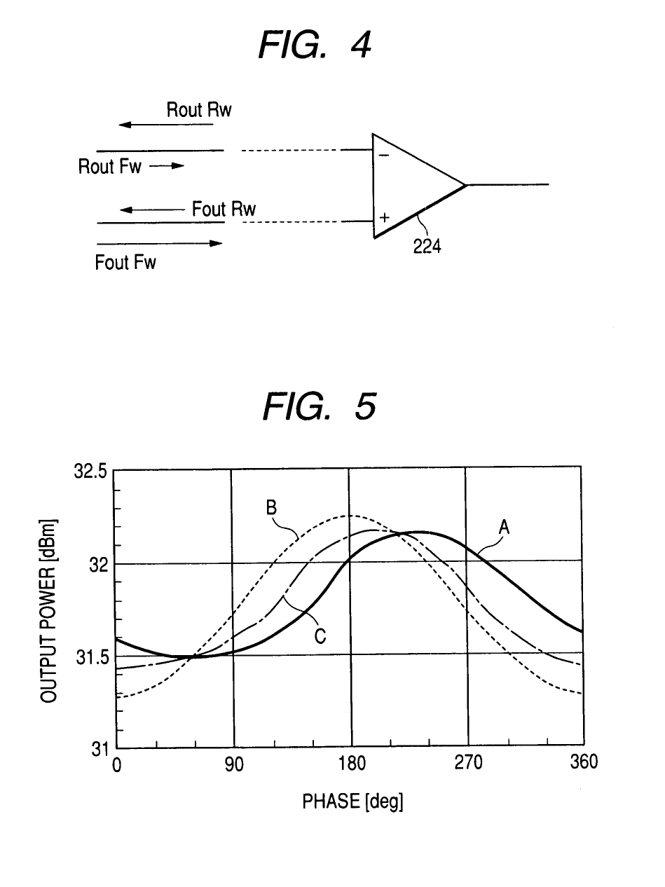

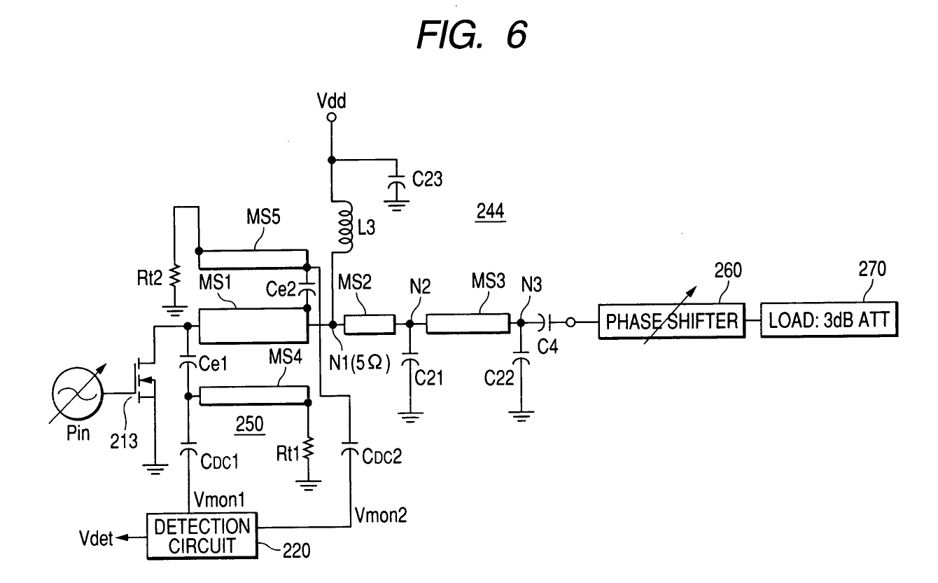

FIG. 5 illustrates a result of simulation of the RF power module shown in FIG. 1 using the power coupler of the embodiment. More specifically, an attenuator 270 of 3 dB is connected to the output terminal OUT as a load via a phase shifter 260 as shown in FIG. 6, and the output voltage detection circuit 220 is connected to the power coupler 250. A change in the output voltage Pout is represented by a solid line A when an input voltage Pin is varied such that the output voltage Vdet of the output voltage detection circuit 220 is constant even if the phase is changed by the phase shifter 260.

Suppose a coupler on the one-side subline disclosed in the prior invention (patent document 1) is used to take the monitor voltage only from the beginning side of the subline MS4 in the output voltage detection circuit 220 instead of using the power coupler of the embodiment. In this case, a change in the output power Pout with respect to the phase is represented by a broken line B. The graph shows that the change in the output power represented by the solid line A is smaller than that by the broken line B. That is, the high frequency power amplifier circuit which is adapted to perform the power control using the power coupler of the embodiment controls the output power Pout with respect to the change in load relatively better than the above-mentioned prior art case. Thus, the application of the embodiment can prevent the flowing of excess current, and reduce distortion of an output waveform due to the change in load thereby to reduce a decrease in accuracy of modulation in a case where the transmission is carried out accompanied by the control of amplitude in addition to the phase control, such as in an EDGE (Enhanced Data Rates for GMS Evolution) mode.

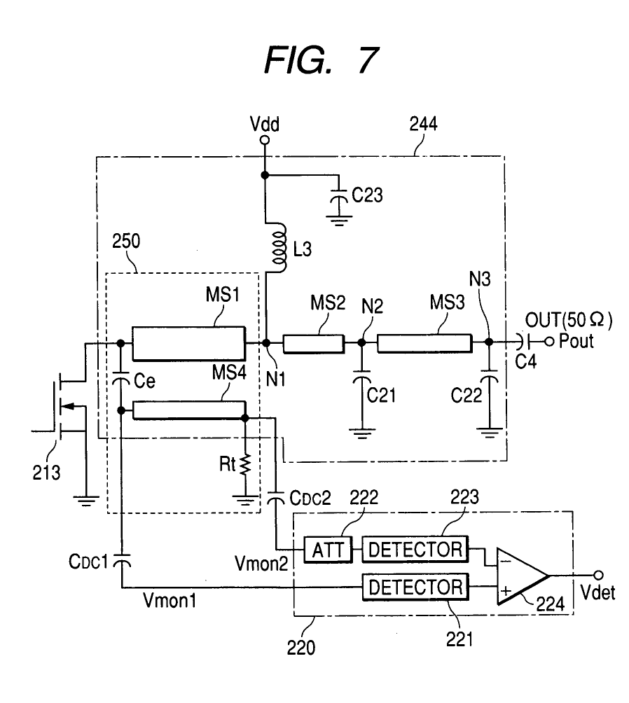

FIG. 7 shows another configuration example of the RF power module to which a power coupler of a second preferred embodiment of the invention is applied.

An power coupler 250 of this embodiment is provided by omitting the microstripline MS5 of the power coupler from the first embodiment shown in FIG. 1, taking the reflected-wave component from the termination of the microstripline MS4 via a coupling capacitor Ce2, and attenuating the reflected-wave component taken by the attenuator 222 to supply it to the detection circuit 223. A change in the output voltage Pout is represented by a dashed-dotted line C in FIG. 5 when an input voltage Pin is varied such that the output voltage Vdet of the output voltage detection circuit 220 is constant even if the phase of the load is changed in the RF power module using the power coupler of the second embodiment.

FIG. 5 shows that even the structure of the second embodiment can obtain the detection output having a little fluctuation of the output power Pout, that is, the detection output having a little influence of the reflected wave, as compared to the prior invention of the patent document 1 (represented by a broken line B) which is adapted to take the monitor voltage only from the beginning side using the one-side subline coupler. Since in this embodiment, the single microstripline MS4 may be provided as a subline only on the one side of the main line MS1, and only one termination resistor Rt may be provided, the number and spaces of component parts of the power coupler can be decreased as compared with that of the first embodiment shown in FIG. 1, thereby advantageously resulting in miniaturization of the module.

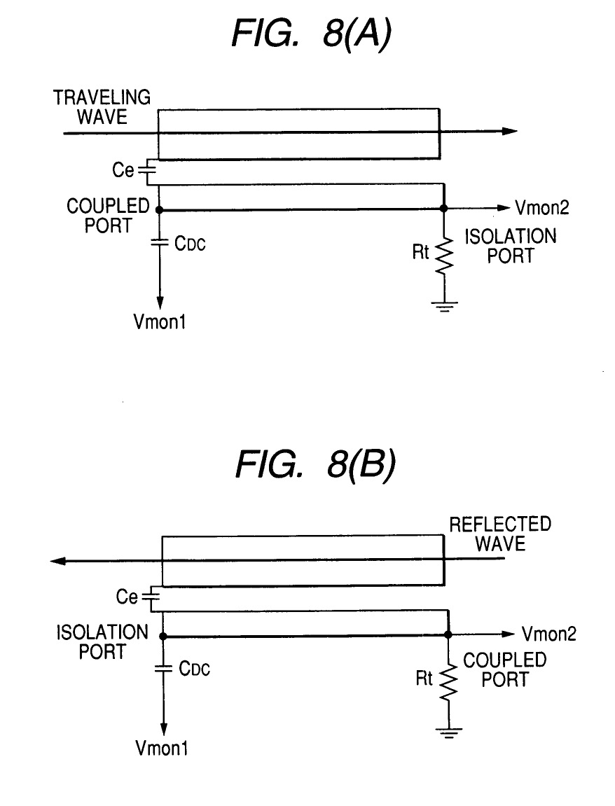

The following is a reason why the influence of the reflected wave can be reduced in the same manner as the first embodiment, which takes the reflected-wave component from the second subline, even if the reflected-wave component is taken from the termination of the microstripline MS4 serving as the subline via the coupling capacitor Ce. The reason is based on a directional property of the coupler. That is, taking into consideration the traveling wave on the main line, as shown in FIG. 8A, the beginning side of the subline MS4 is a coupled port (capacitance coupling port), and the termination side of the subline MS4 is an isolation port. In contrast, taking into consideration the reflected wave of the main line, as shown in FIG. 8B, the beginning side of the subline MS4 is an isolation port, and the termination side of the subline MS4 is a coupled port.

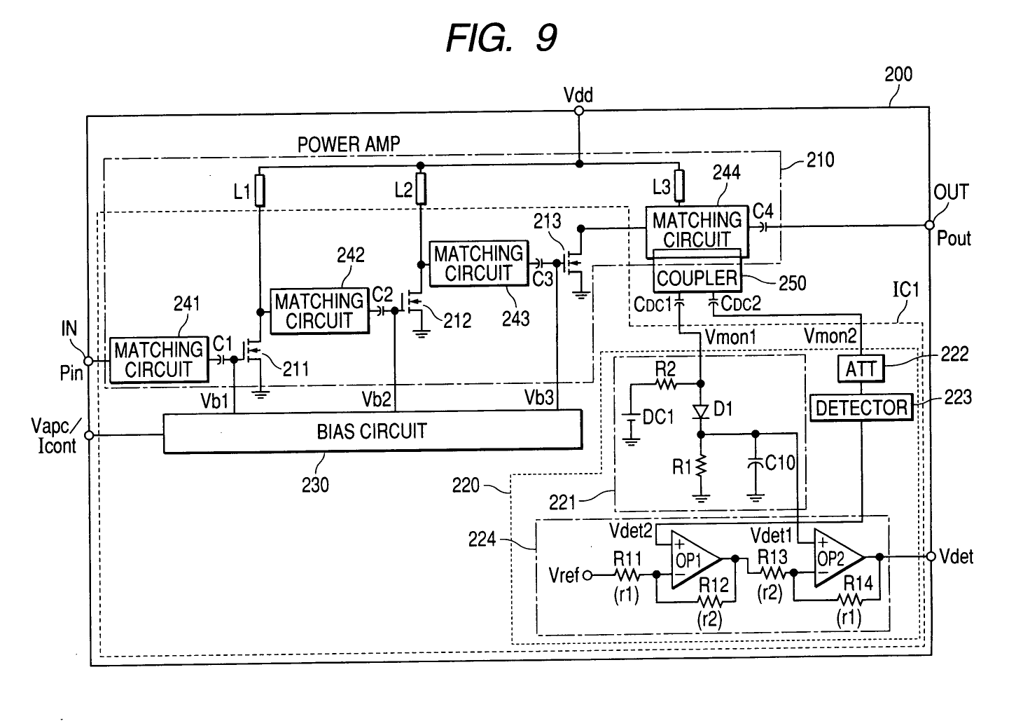

FIG. 9 shows the detailed configuration of the RF power module to which the directional coupler of the second embodiment is applied. In FIG. 9, the repeated explanation of the same circuit and element as those shown in FIG. 1 and FIG. 7 will be omitted.

An RF power module 200 of this embodiment includes a high frequency power amplifier 210 including the FET for the power amplifier for amplifying an input high frequency signal Pin modulated, and an output power detection circuit 220 for detecting an output power from the high frequency power amplifier circuit 210. The RF power module also includes a bias circuit 230 for controlling an idle current which passes through each FET by applying a bias voltage to the FET for the power amplifier at each stage of the high frequency power amplifier 210, and a power coupler 250 of the embodiment disposed between the matching circuit 244 located at the last stage of the high frequency power amplifier 210 and the output power detection circuit 220.

The high frequency power amplifier 210 of the embodiment may include, but not limited to, three FETs for the power amplifier 211, 212, and 213. Among them, the FETs at the later stage 212, and 213 have gate terminals thereof connected to the drain terminals of the FETs at the preceding stage 211 and 212, and all of these FETs constitute a three-stepped amplifier circuit as a whole. To the gate terminals of the FETs 211, 212, and 213 at each stage is applied gate bias voltages Vb1, Vb2, and Vb3 supplied from the bias circuit 230. The idle currents corresponding to these voltages pass through the respective FETs 211, 212, and 213.

Although a MOSFET is used as each of the elements for the power amplifier 211 to 213 in this embodiment, the invention is not limited thereto. The elements for the power amplifier 211 to 213 may include transistors, such as a bipolar transistor, a GaAsMESFET, a hetero junction bipolar transistor (HBT), and a high electron mobility transistor (HEMT).

To the drain terminals of the FETs 211 and 212 at each stage, is applied the power source voltage Vdd via inductance elements L1 and L2, respectively. Between the gate terminal of the FET 211 at the beginning, and the input terminal, are provided an impedance matching circuit 241 and a direct current cut capacitance element C1, through which the high frequency signal Pin is input to the gate terminal of the FET 211.

An impedance matching circuit 242 and a direct current cut capacitance element C2 are connected to between the drain terminal of the FET 211 at the starting stage, and the gate terminal of the FET 212 at the second stage. Furthermore, an impedance matching circuit 243 and a direct current cut capacitance element C3 are connected to between the drain terminal of the FET 212 at the second stage and the gate terminal of the FET 213 at the last stage. The drain terminal of the FET 213 at the last stage is connected to the output terminal OUT via an impedance matching circuit 244 and a capacitance element C4, so that the direct current component of the high frequency input signal Pin is cut, and an amplified signal Pout of the alternating current component thereof is output.

The detection circuit 221 of the output power detection circuit 220 includes a rectifier diode D1 and a resistor R1 connected in series to between the ground point and the input terminal to which the monitor voltage Vmon1 taken by the power coupler 250 is applied via a capacitor CDC1, a direct-current voltage source DC1 serving as an operating point for applying the bias voltage to the anode terminal of the diode D1 via a resistor R2, and a smoothing capacitor C10. A current passes through the resistor R1, the current being obtained by half-wave rectifying an alternating current waveform so as to have its waveform proportional to the alternating current waveform input via the capacitor CDC1. The current is converted into a voltage, and smoothed by the smoothing capacitor C10 to be output as the detection voltage Vdet1.

The detection circuit 223 for detecting the reflected-wave component has the same configuration as that of the detection circuit 221, and thus the detailed illustration of the configuration will be omitted in the figure. As the attenuator 222, a π type attenuator or the like including the resistor elements in a π type shape may be used. The subtracting circuit 224 includes a differential amplifier consisting of two operational amplifiers OP1 and OP2 sequentially connected to each other. An output voltage Vdet2 of the second detection circuit 223 is input to the non-inverting input terminal of the operational amplifier OP1, and an output voltage Vdet1 of the first detection circuit 221 is input to the non-inverting input terminal of the operational amplifier P2.

A reference voltage Vref is applied to an inverting input terminal of the operational amplifier OP1 via a resistor R11, and an output of the operational amplifier OP1 is input to the non-inverting input terminal of the operational amplifier OP2 via a resistor R13. A feedback resistor R12 is connected to between the output terminal of the operational amplifier OP1 and the inverting input terminal. A voltage obtained by resistor-dividing the output voltage of the operational amplifier OP1 and the reference voltage Vref by the resistors R11 and R12 is applied to the inverting input terminal of the operational amplifier OP1.

A feedback resistor R14 is connected to between the output terminal and the inverting input terminal of the operational amplifier OP2. A voltage obtained by resistor-dividing the output voltage of the operational amplifier OP2 and the output of the operational amplifier OP1 by the resistors R13 and R14 is applied to the inverting input terminal of the operational amplifier OP2. Note that the input resistor R11 of the operational amplifier OP1 and the feedback resistor R14 of the operational amplifier OP2 are set to have the same resistance value, and the feedback resistor R12 of the amplifier OP1 and the input resistor R13 of the amplifier OP2 are also set to have the same resistance value.

When the resistance value of the resistors R11 and R14 is r1, the resistance value of the resistors R12 and R13 is r2, a difference between the input voltages Vdet1 and Vdet2 of the two amplifiers in the whole circuit is ΔVin (=Vdet1−Vdet2), and a gain of the whole circuit is Kg, the following equation is satisfied: Kg=(r1+r2)/r2, and the output of the circuit Vdet is represented by Vdet≅Voff+Kg·ΔVin. That is, the differential amplifier 224 outputs as the detection voltage Vdet, a voltage in proportional to the difference in potential between the Vdet1 and Vdet2, and which is shifted by Voff.

The differential amplifier 224 shown in FIG. 9 can change its gain easily by varying the ratio of the resistance of the resistor R11, R14 to that of the resistor R12, R13. The use of such a differential amplifier facilitates adjustment of the detection sensitivity. When these resistors are external resistors, the detection sensitivity can be adjusted after manufacturing the IC.

The output power detection circuit 220 of the embodiment is configured such that the reference voltage Vref is applied as a direct current voltage to the inverting input terminal of the operation amplifier OP1 at the preceding stage of the differential amplifier 224. This is based on the following reason. When the output level of a baseband circuit for supplying an output level indicating signal Vramp to an error amplifier for controlling the output power is intended to be zero (0), the Vramp signal of 0 V cannot sometimes be output completely. In this case, when the detection voltage Vdet fed from the output power detection circuit 220 to the error amplifier is 0 V, a control voltage Vapc output from the error amplifier may be higher than 0 V, and the output power Pout may not be “zero (0)”.

The RF power module 200 of this embodiment includes a semiconductor integrated circuit enclosed by the broken line. That is, each element of the power amplifier 210 (except for the inductance elements L1 to L3, and the impedance matching circuit 244), each element of the bias circuit 230, and each element of the output power detection circuit 220 are configured in the form of a semiconductor integrated circuit IC1 formed on one semiconductor chip made of, for example, a single crystal silicon. The semiconductor chip, the inductance elements L1 to L3 and impedance matching circuit 244 of the power amplifier 210, the power coupler 250, and the direct current cut capacitance element CDC are mounted on the one ceramic substrate to constitute the RF power module. As the capacitance element CDC, the discrete parts may be used. The output power detection circuit 220 may also be composed of discrete parts, including a diode element, a resistor element, a capacitance element, or the like.

Thus, the RF power module of the present embodiment utilizes the power coupler 250 whose size is small as compared to the directional coupler, and thus can be reduced in size, while easily making the output power detection circuit 220 together with the main parts of the power amplifier 210 and the bias circuit 230 in the form of the semiconductor integrated circuit. This can decrease the number of parts constituting the module, thereby miniaturizing the module.

In the description using FIG. 9, each element of the power amplifier 210, the bias circuit 230, and the output power detection circuit 220, except for the inductance elements L1 to L3 and the impedance matching circuit 244, are configured in the form of one semiconductor integrated circuit. This is not limited, but includes the following. The FET 211 at the first stage and the FET 212 at the second stage of the power amplifier 210, the bias circuit 230, and the output power detection circuit 220 are also configured in the form of one semiconductor integrated circuit. That is, the FET 213 at the last stage of the power amplifier 210, the impedance matching circuits 241 to 244, and the inductance elements L1 to L3 may be external elements outside the IC.

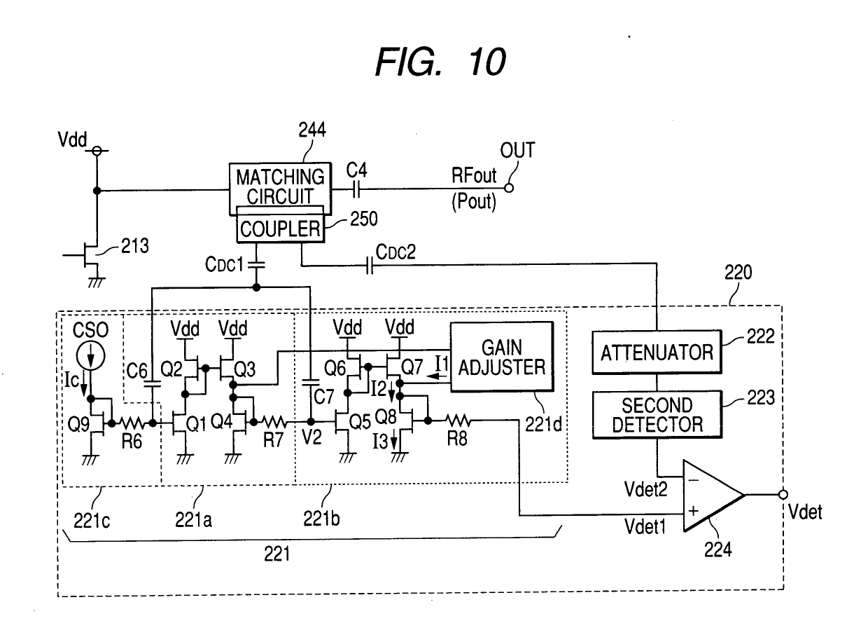

FIG. 10 shows another embodiment of the output power detection circuit 220.

The output power detection circuit 220 of this embodiment employs a two-stepped detection type circuit, namely, the first detection circuit 221 and the second detection circuit 222. The second detection circuit 222 has the same configuration as that of the first detection circuit 221, and thus the illustration thereof will be omitted. The first detection circuit 221 will be described below.

The first detection circuit 221 includes a first detection stage 221a, a second detection stage 221b, a bias generating circuit 221c, and gain adjuster 221d. The first detection stage 221a includes a MOS transistor Q1 for detection having its gate terminal connected to the power coupler 250 via the capacitor C6, a P channel MOS transistor Q2 connected in series to the transistor Q1, a MOS transistor Q3 current-mirror connected to the transistor Q2, and a MOS transistor Q4 for current-voltage conversion, connected in series to the transistor Q3.

The second detection stage 221b includes a capacitor C7 connected in parallel to the capacitor C6, a MOS transistor Q5 for detection having its gate connected to the other terminal of the capacitor C7, a P channel MOS transistor Q6 connected in series to the transistor Q5, a MOS transistor Q7 current-mirror connected to the transistor Q6, and a MOS transistor Q8 for the current-voltage conversion connected in series to the transistor Q7. The bias generating circuit 221c applies a gate bias voltage as an operating point to the MOS transistor Q1 for detection of the first detection stage 221a.

The output power detection circuit 220 of the embodiment is configured to supply as a bias voltage for giving an operating point, a voltage converted by the MOS transistor Q4 for the current-voltage conversion of the first detection stage 221a, to the gate terminal of the MOS transistor Q5 for detection of the second detection stage 221b via the resistor R7. Furthermore, the output voltage of the first detection stage 221a is input to the gain adjuster 221d, which is configured to output the current according to the output voltage of the first detection stage 221a, and to cause the current to flow into the drain terminal of the transistor Q8 for the current-voltage conversion.

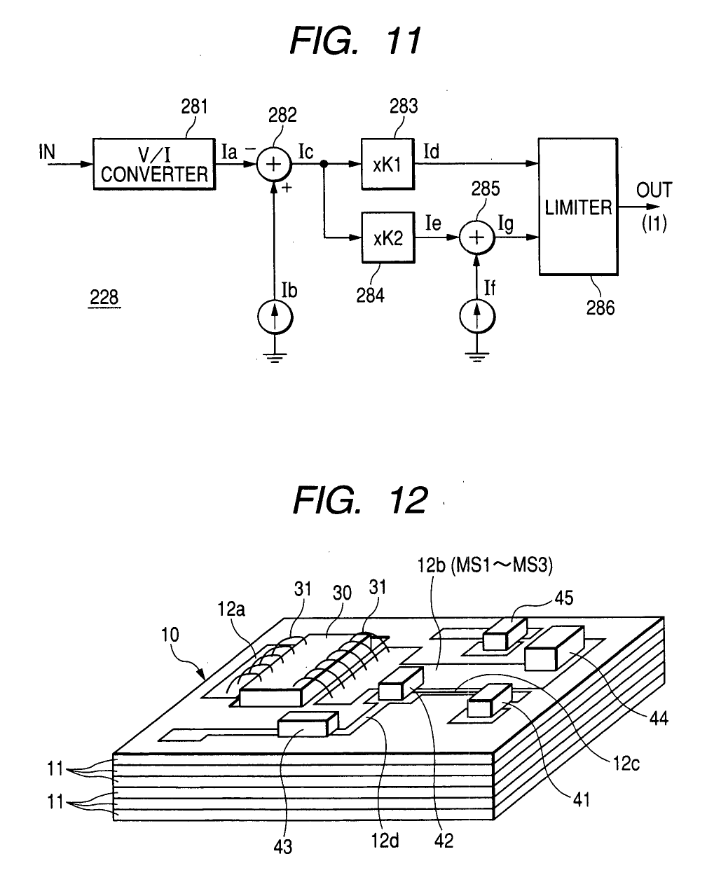

The output voltage V2 of the first detection stage 221a is a voltage adapted to change in proportion to the square of the output power Pout. Such a voltage is input to the gain adjuster 221d, so that the gain adjuster 221d generates a current 11 adapted to change substantially in proportion to the output power of the first detection circuit 221, that is, to the output power Pout, thus causing the current to flow into the output stage of the second detection stage 221b. This can enhance the sensitivity of the second detection stage 221b at an area where the output level is low, while reducing the sensitivity of the second detection stage 221b at an area where the output level is high. Thus, at the high output level area, the sensitivity of the whole output power detection circuit 220 is prevented from becoming too high, so that the appropriate output level detection signal can be output over the whole control area. The gain adjuster 221d utilizes a circuit having a configuration shown in FIG. 11.

A bias generating circuit 221c for giving a bias to the first detection stage 221a includes a constant current source CS0, a diode-connected MOS transistor Q9 for converting the constant current Ic from the constant current source CS0 into a voltage, and a resistor R6 connected to between the transistor Q9 and the gate terminal of the transistor Q1. The constant current source CS0 causing the constant current Ic to pass through can be composed of a constant voltage circuit for generating a constant voltage having a little temperature dependency, such as a band gap reference circuit, a transistor for converting the generated constant voltage to a current, and a current mirror circuit for supplying a current in proportion to the current passing through the transistor. Instead of constituting the constant current source CS0 as the inner circuit, the source may be provided from the outside of the chip. Furthermore, instead of the constant current, the constant voltage may be given from the outside of the chip.

In the embodiment, a gate bias voltage value of the MOS transistor Q1 for detection of the first detection stage 221a is set to a voltage value near the threshold voltage of the transistor Q1 so that the transistor Q1 can perform the grade-B amplification operation. Thus, the current which is proportional to an alternating current signal input via the capacitor C6, and which is formed by half-wave rectifying the alternating current signal passes through the MOS transistor Q1. The drain current of the transistor Q1 includes a direct current component in proportional to the amplitude of the alternating signal input.

The drain current of the transistor Q1 is transferred to the Q3 side by the current mirror circuit composed of the Q2 and Q3, and is converted to a voltage by the diode-connected transistor Q4. The relationship between the MOS transistors, namely, Q1/Q4, and Q2/Q3 are set to have the predetermined size ratio (for example, 1:1). Thus, when the properties of the MOS transistors Q1 and Q2 (in particular, the threshold voltage) vary due to the manufacturing variations, the properties of the MOS transistors Q4 and Q3 that are opposed to a pair of transistors Q1 and Q2 are also varied. As a result, the influences due to the variations in properties are offset to each other, and the detection voltage which is not influenced by the variations in properties of the MOS transistors appears in the drain terminal of the MOS transistor Q4. The same goes for the second detection stage 221b. The voltage converted by a transistor QB corresponding to the Q4 is supplied to the subtracting circuit 224 as a detection output of the first detection circuit 221.

The gain adjuster 221d, as shown in FIG. 11, includes a voltage-current conversion circuit 281 for converting the input voltage, namely, an output voltage of the first detection stage 221a, into the current, a subtracter 282 for performing subtraction between a converted current Ia and a current Ib from a constant current source, and amplifiers 283 and 284 for amplifying the current subtracted by a factor of K1, and K2, respectively. The adjuster also includes an adder 285 for adding the constant current If to the output current Ie of the amplifier 284, and a limiter 286 for limiting an output current Id of the amplifier 283 by an output current Ig of the adder 285. The amplifiers 283, and 284 are to improve the sensitivity at the low power area, and its gains K1, and K2 are set to, for example, K1=3, K2=1.5. The reason why the constant current If is added to the output current Ie from the amplifier 284 is also to improve the sensitivity at the low power area. The value If is set to, for example, 0.1 mA.

The output current Id of the amplifier 283 and the output current Ig of the adder 285 are supplied to the limiter 286, from which a gain adjustment current I1 having a desired property is output, and added to a current I2 from the transistor Q7 of the second detection stage 221b to be fed to the transistor Q8. This can improve the detection sensitivity of the output power detection circuit 220 at an area of the low output level.

FIG. 12 shows an example of a device structure of the power module 200 of the embodiment. Note that FIG. 12 does not show the precise structure of the RF power module of the embodiment, but illustrates the schematic structure of the RF power module for clarification in which some parts and wires are omitted.

As shown in FIG. 12, a module body 10 of the embodiment is constituted of an integrated pile of a plurality of dielectric layers 11 made of a ceramic plate, such as alumina. A conductive layer formed in a predetermined pattern and made of conductive material, such as copper, with its surface subjected to a gold plating is formed on the front and back sides of each dielectric layer 11. Reference numerals 12a to 12d are conductive patterns made of the conductive layer. To connect the conductive patterns on the front and back sides of each dielectric layer 11, each conductive layer 11 is provided with a hole (not shown) which is called the through-hole, into which a conductor is filled.

The module of the embodiment shown in FIG. 12 includes six laminated pieces of the dielectric layers 11. Substantially over the whole back surface side of the lowest dielectric layer, the conductive layer is formed as a ground layer, which provides the ground potential GND. Also on the front and back surfaces of the first to fifth respective dielectric layers, the conductive patterns constituting the microstriplines, each serving as a transmission line, and the conductive layers serving as the ground layers are formed.

On the first dielectric layer 11, a semiconductor chip 30 with the semiconductor integrated circuit IC1 formed thereon is mounted, and an electrode (pad) on the upper surface of the semiconductor chip 30 and predetermined conductive layers 12a, and 12b on the surface of the dielectric layer 11 are electrically connected to each other with a bonding wire 31. Futhermore, on the surface of the first dielectric layer 11, are formed the conductive patterns 12b, and 12c constituting the microstriplines MS1, MS2, MS3, MS4, and MS5, which constitute the matching circuit 244, and the power coupler 250 shown in FIG. 1.

In addition, discrete parts 41, 42, and 43 for use as the resistor element Rt, the capacitance elements Ce and CDC, and the like constituting the power coupler 250 for taking the monitor voltage from the matching circuit to the output power detection circuit are mounted. Also, parts 44 and 45 for use as the direct current capacitance element C4, the inductance element L3, and the like are mounted. Each of the capacitors C21 and C22 of the impedance matching circuit 244 may be a discrete part, but in the embodiment, is constituted of an inner capacitor including the conductive pattern 12b, and a conductive pattern not shown formed on the back surface of the first dielectric layer 11 so as to be opposed to a part of the conductive pattern 12b. Passive elements, including a resistor element Rt and capacitance elements Ce and CDC constituting the matching circuit 244 and the power coupler 250, the direct current cut capacitance element C4, the inductance element L3, and the like may be constituted using parts called IPC (Integrated Passive Component) mounted on or inserted into a dielectric base, such as a glass.

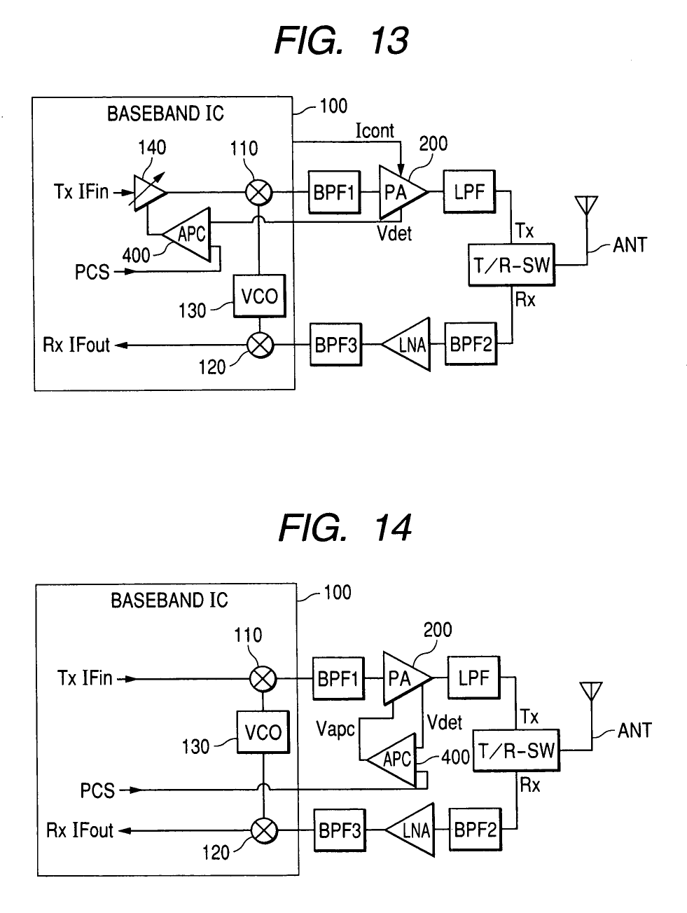

FIG. 13 shows an example of a schematic configuration of a wireless communication system to which the invention is usefully applied.

In FIG. 13, an ANT denotes an antenna for transmission and reception of a signal radio wave, and a T/R-SW denotes a selector switch for transmission and reception thereof. Reference numeral 100 denotes a semiconductor integrated circuit for high frequency signal processing (baseband IC) which includes a mixer 110 on the transmission side for modulating and up-converting a transmission signal in the GSM or DCS system, a mixer 120 on the reception side for demodulating and down-converting a reception signal, and a VCO (voltage control oscillation circuit) 130 for generating a local oscillation signal to be mixed with the transmission and reception signals. The baseband IC 100 has functions of generating I and Q signals, of processing the I and Q signals extracted from the reception signal, and of outputting an output power control signal PCS, based on the transmission data (baseband signal). Reference numeral 200 is an RF power module of the embodiment.

The transmission signal modulated by the baseband IC100 is amplified by the RF power module 200 via a bandpass filter BPF1 for removing unnecessary waves, and fed to the antenna ANT via a lowpass filter LPF1 for removing a high frequency component, and via the transmission and reception selector switch T/R-SW. In contrast, the reception signal received by the antenna ANT is fed and amplified to a low-noise amplifier LNA via the transmission and reception selector switch T/R-SW, and a bandpass filter BPF2 for removing unnecessary waves from the reception signal. The reception signal amplified by the LNA is input into the baseband IC 100 via a bandpass filter BPF3, and demodulated and processed by a demodulation circuit (mixer) 120.

In the present wireless communication system, an automatic power control circuit (APC) 400 for generating an output control voltage Vapc is provided in the baseband IC 100 based on the output power detection signal Vdet output from the output power detection circuit 220 of the RF power module 200, and an output power control signal PCS output from the baseband IC100. In addition, a variable gain amplifier 140 is provided at the preceding stage of the mixer 110 for transmission. The output Vapc of the automatic power control circuit (APC) 400 is supplied to the variable gain amplifier 140, whereby a feedback control operation for controlling a gain of the variable gain amplifier 140 is performed so as to match the Vdet to the PCS.

It should be noted that in this system, a predetermined bias current Icont is supplied from the basebasnd IC100 to the bias circuit 230 of the RF power module 200, and then the gain of the high frequency power amplifier circuit 210 is set. Such a system is effective, in particular, in applications to an EDGE or CDMA type portable telephone for performing phase modulation and amplitude modulation. In the system using the RF power module 200 including the power coupler of the embodiment, the detection voltage Vdet precisely corresponding to the output power is supplied to the automatic power control circuit (APC) 400. Thus, this system can be applied to a GSM type portable telephone for performing a GMSK modulation.

Although in FIG. 13, a control voltage Vapc from the APC circuit 400 is supplied to the variable gain amplifier 140 disposed at the preceding stage of the mixer 110 to change its gain, the invention is not limited thereto. Alternatively, a variable gain amplifier may be provided between the mixer 110 and the RF power module 200 to change its gain by the control voltage Vapc from the APC circuit 400.

FIG. 14 shows another configuration example of the wireless communication system to which the invention is usefully applied.

In the wireless communication system of the embodiment, an automatic power control circuit (APC) 400 is provided for generating the output control voltage Vapc based on the output power detection signal Vdet output from the output power detection circuit 220 of the RF power module 200, and the output power control signal PCS output from the baseband IC 100. The output Vapc of the APC circuit 400 is supplied to the bias circuit 230 of the RF power module 200, where by a feed back control operation for controlling a gain of the high frequency power amplifier circuit 210 within the RF power module 200 is performed so as to match the Vdet to the PCS. Such a system is useful in application to the GSM type portable telephone for performing the GMSK modulation.

Although in the above description, the invention made by the applicants has been explained in detail based on the preferred embodiments, the invention is not limited to these embodiments described herein. It will be apparent to those skilled in the art that various modifications and variations can be made to the embodiments without departing from the spirit and scope of the present invention. For example, the high frequency power amplifier circuit of the embodiment has a three-stepped connection of the FETs for the power amplifier, but may have a two-stepped structure, or a four- or more stepped structure.

Although in the above-mentioned embodiments, the differential amplifier including two operational amplifiers connected to each other in series is used as a subtracting circuit for subtracting the output voltage Vdet2 of the second detection circuit from the output voltage Vdet1 of the first detection circuit and, for outputting the voltage obtained through the subtraction as the detection voltage Vdet, the invention is not limited thereto. Alternatively, a subtracting circuit may be used in which a voltage to be calculated is input to one operational amplifier via an input resistor.

In the above description, the invention made by the applicants is mainly applied to the RF power module constituting the portable telephone which belongs to a background field of the invention, but is not limited thereto. The invention can be applied to an RF power module constituting a wireless LAN.

What is claimed is:

1. An electronic part for a high frequency power amplifier, comprising:
an input terminal for receiving a high frequency signal to be amplified;
a power amplifier circuit for amplifying the high frequency signal;
an output terminal for outputting the high frequency signal amplified by the power amplifier circuit;
a directional coupler provided at a point on an output line connecting the power amplifier circuit with the output terminal; and
an output power detection circuit for detecting an amount of an output power from the power amplifier circuit by receiving a signal detected by the directional coupler, and for generating a signal for controlling an output from the power amplifier circuit,
wherein the output power detection circuit includes first detection means for detecting a traveling-wave component of the high frequency signal taken from a first terminal of the directional coupler via a first capacitance element, and directed from the power amplifier circuit to the output terminal, and for outputting a detection voltage, second detection means for detecting a reflected-wave component of the high frequency signal taken from a second terminal of the directional coupler via a second capacitance element, and directed from the output terminal to the power amplifier circuit, and for outputting a detection voltage, and an arithmetic circuit for outputting a voltage or a current according to a difference in potential between the detection voltage of the first detection means and the detection voltage of the second detection means,
wherein the directional coupler includes a first subline and a second subline respectively disposed in parallel to and in the vicinity of a part of a main line through which the output of the power amplifier circuit is transmitted, a third capacitance element connected to between the main line and a nearer one of ends of the first subline to an output terminal of the power amplifier circuit, a first resistor element connected to between a constant potential point and a farther one of the ends of the first subline from the output terminal of the power amplifier circuit, a fourth capacitance element connected to between the main line and a farther one of ends of the second subline from the output terminal of the power amplifier circuit, and a second resistor element connected to between a constant potential point and a nearer one of the ends of the second subline to the output terminal of the power amplifier circuit,
wherein the first terminal of the directional coupler is positioned at the nearer one of the ends of the first subline to the output terminal of the power amplifier circuit, the nearer end being connected to one terminal of the third capacitance element, and
wherein the second terminal of the directional coupler is positioned at the farther one of the ends of the second subline from the output terminal of the power amplifier circuit, the farther end being connected to one terminal of the fourth capacitance element.

2. The electronic part for the high frequency power amplifier according to claim 1, wherein the output power detection circuit includes an attenuator disposed between the second terminal of the directional coupler and the arithmetic circuit for attenuating the reflected-wave component taken via the second capacitance element.

3. The electronic part for the high frequency power amplifier according to claim 2, wherein an attenuation factor of the attenuator is set such that the component in a reflected-wave direction taken via the second capacitance element is attenuated to the same level as that of a component in a reflected-wave direction included in an alternating current signal taken via the first capacitance element.

4. The electronic part for the high frequency power amplifier according to claim 3, wherein a capacitance value of the first capacitance element is the same as that of the second capacitance element, a capacitance value of the third capacitance element is the same as that of the fourth capacitance element, and the capacitance value of the first and second capacitance elements is larger than that of the third and fourth capacitance elements.

5. The electronic part for the high frequency power amplifier according to claim 1, wherein the power amplifier circuit includes one or two or more semiconductor integrated circuits, and the main line and the first and second sublines include conductive layers formed on an insulating substrate with the semiconductor integrated circuit mounted thereon.

6. The electronic part for the high frequency power amplifier according to claim 5, wherein the main line included in the directional coupler is a microstripline constituting an impedance matching circuit provided at a subsequent stage of the output terminal of the power amplifier circuit.

7. An electronic part for a high frequency power amplifier, comprising:
an input terminal for receiving a high frequency signal to be amplified;
a power amplifier circuit for amplifying the high frequency signal;
an output terminal for outputting the high frequency signal amplified by the power amplifier circuit;
a directional coupler provided at a point on an output line connecting the power amplifier circuit with the output terminal; and
an output power detection circuit for detecting an amount of an output power from the power amplifier circuit by receiving a signal detected by the directional coupler, and for generating a signal for controlling an output from the power amplifier circuit,
wherein the output power detection circuit includes first detection means for detecting a traveling-wave component of the high frequency signal taken from a first terminal of the directional coupler via a first capacitance element, and directed from the output power detection circuit to the output terminal, second detection means for detecting a reflected-wave component of the high frequency signal taken from a second terminal of the directional coupler via a second capacitance element, and directed from the output terminal to the output power detection circuit, and an arithmetic circuit for outputting a voltage or a current according to a difference in potential between a detection voltage of the first detection means and a detection voltage of the second detection means,
wherein the directional coupler includes a subline disposed in parallel to and in the vicinity of a part of a main line through which the output of the power amplifier circuit is transmitted to the output terminal, a third capacitance element connected to between the main line and a nearer one of ends of the subline to an output terminal of the power amplifier circuit, and a resistor element connected to between a constant potential point and a farther one of the ends of the subline from the output terminal of the power amplifier circuit,
wherein the first terminal of the directional coupler is positioned at the nearer one of the ends of the subline to the output terminal of the power amplifier circuit, the nearer end being connected to one terminal of the third capacitance element, and
wherein the second terminal of the directional coupler is positioned at the farther one of the ends of the subline from the output terminal of the power amplifier circuit, the farther end being connected to one terminal of the resistor element.

8. The electronic part for the high frequency power amplifier according to claim 7, wherein the output power detection circuit includes an attenuator disposed between the second terminal of the directional coupler and the arithmetic circuit for attenuating the reflected-wave component taken via the second capacitance element.

9. The electronic part for the high frequency power amplifier according to claim 8, wherein an attenuation factor of the attenuator is set such that the component in a reflected-wave direction taken via the second capacitance element is attenuated to the same level as that of a component in a reflected-wave direction included in an alternating current signal taken via the first capacitance element.

10. The electronic part for the high frequency power amplifier according to claim 9, wherein a capacitance value of the first capacitance element is the same as that of the second capacitance element, and the capacitance value of the first and second capacitance elements is larger than that of the third capacitance element.

11. The electronic part for the high frequency power amplifier according to claim 10, wherein the power amplifier circuit includes one or two or more semiconductor integrated circuits, and the main line and the subline include conductive layers formed on an insulating substrate with the semiconductor integrated circuit mounted thereon.

12. The electronic part for the high frequency power amplifier according to claim 11, wherein the main line included in the directional coupler is a microstripline constituting an impedance matching circuit provided at a subsequent stage of the output terminal of the power amplifier circuit.
